(19) United States
(12) Patent Application Publication
(10) Pub. No.: US 2025/0051910 A1
(43) Pub. Date: Feb. 13, 2025

(54) CHAMBER COMPONENT FOR IMPROVED CLEANING EFFICIENCY

(71) Applicant: Applied Materials, Inc., Santa Clara, CA (US)

(72) Inventors: Shinichi OKI, Chiba-Ken (JP); Yoshinobu MORI, Tokyo (JP); Yuji AOKI, Yokohama-Shi Kanagawa-Ken (JP)

(73) Assignee: Applied Materials, Inc., Santa Clara, CA (US)

(21) Appl. No.: 18/366,433

(22) Filed: Aug. 7, 2023

(51) Int. Cl. C23C 16/44; C23C 16/458; C23C 16/46; C30B 25/10; C30B 25/12; H01L 21/687

(52) U.S. Cl. CPC C23C 16/4408; C23C 16/4585; C23C 16/46; C30B 25/10; C30B 25/12; H01L 21/68735; B08B 5/00

(57) ABSTRACT

A pre-heat ring and a process chamber having the same are described herein. In one example, a process chamber for film deposition comprises a chamber volume, a substrate support disposed in the chamber volume, the substrate support having a radially outward surface, and a pre-heat ring surrounding the substrate support. The pre-heat ring comprises a tapered wall facing the radially outward surface. The tapered wall narrows towards a top surface of the pre-heat ring and towards the substrate support.

### BACKGROUND

### Field

Embodiments of the present disclosure generally relate to a chamber component for processing a substrate and a process system having the same. More specifically, the embodiments described herein relate to a pre-heat ring in a semiconductor processing chamber.

### Description of the Related Art

Semiconductor substrates are processed for a wide variety of applications, including the fabrication of integrated devices and micro-devices. One method of substrate processing includes depositing a material, such as a dielectric material or a conductive metal, on an upper surface of the substrate in a processing chamber. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support and thermally decomposing the process gas to deposit a material from the process gas onto the substrate surface.

During epitaxial deposition, a process gas is heated and flowed over a substrate and a top surface of a susceptor. The process gas temperature is adjusted as the gas passes over a gas heating component to raise activation energy for formation of a film or layer on the substrate as the process gas flows over the substrate. The temperature of the process gas between the front end and back end of a substrate during processing varies. Additional purge gases introduced in the chamber may interact with the process gas temperature and flow path creating further processing variations. The non-uniformity of the process gas temperature and flow path causes non-uniform deposition along the length of the substrate and undesired depositions on chamber components. The non-uniform deposition is compensated for through rotation of the substrate and additional gas heating components however, significant amounts of processing gas are still lost to undesired depositions. A chamber cleaning cycle is utilized to clean the undesired depositions. Each cleaning cycle contributes to increased cleaning costs, operational chamber downtime, and reduced product.

Therefore, there is a need for improved chamber cleaning efficiency within a processing chamber by reducing undesired depositions.

### SUMMARY

A pre-heat ring and a process chamber having the same are described herein. In one example, a process chamber for film deposition comprises a chamber volume, a substrate support disposed in the chamber volume, the substrate support having a radially outward surface, and a pre-heat ring surrounding the substrate support. The pre-heat ring comprises a tapered wall facing the radially outward surface. The tapered wall narrows towards a top surface of the pre-heat ring and towards the substrate support.

A pre-heat ring and a process chamber having the same are described herein. In one example, a pre-heat ring comprises annular body. The annular body comprises a top surface, an outer bottom surface, an outer wall, an inner wall, an inner bottom surface, and a tapered wall. The outer bottom surface is disposed parallel to the top surface. The outer wall extends between the top surface and the outer bottom surface. The inner wall is disposed substantially parallel to the outer wall and extends from the outer bottom surface toward the top surface, at least a portion of the top surface extends radially inward of the inner wall. The inner bottom surface is disposed substantially parallel to the outer bottom surface and extends radially inward from the inner wall. The tapered wall extends between to the top surface and the inner bottom surface, the tapered wall is at an angle greater than 0 degrees and less than 90 degrees relative to inner bottom surface and the tapered wall has a length of about 1 mm to about 30 mm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional side view of a process chamber, according to embodiments of the present disclosure.

FIG. 2 is a partial schematic cross-sectional view of the process chamber, according to embodiments of the present disclosure.

FIG. 3 is a schematic cross-sectional view of the pre-heat ring, according to embodiments of the present disclosure.

FIG. 4 is a prospective view of a pre-heat ring, according to embodiments of the present disclosure.

FIG. 5 is a schematic cross-sectional view of a pre-heat assembly, according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A pre-heat ring with a tapered body, and processing chamber having the same, are described herein. The tapered body of the pre-heat ring can beneficially be used in a semiconductor processing chamber, such as an epitaxial deposition chamber. The tapered body of the pre-heat ring is configured to provide flow control of purge gases into the processing volume within the deposition chamber, and therefore increase chamber cleaning efficiency.

Process gases (e.g., precursor gases) react with the surface of the substrate to form a film. The rate of reaction to form the film increases with an increase in the temperature of the process gas. The process gases are often heated by a heating component, such as a pre-heat ring, before the process gases flow over the substrate. However, the lateral flow path of the process gases over the substrate is interrupted by a purge gas flow. The purge gas flow pushes the laterally flowing process gases in an upward direction towards chamber components within the processing volume. The chamber components, such as the upper transmissive window, may undesirably be coated with material deposited from the process gases. Depositions on the upper transmissive window are undesirable because radiation through the window is diminished causing process variation, while the substrate depositions rates and film quality is reduced. Furthermore, undesired depositions yield results in a need to undesirably increase the frequency of cleaning chamber components. The pre-heat ring with a tapered body reduces the purge gas the amount of the processing gas flow interacting with the upper window, thus extending the service interval while increasing deposited film quality and production rates.

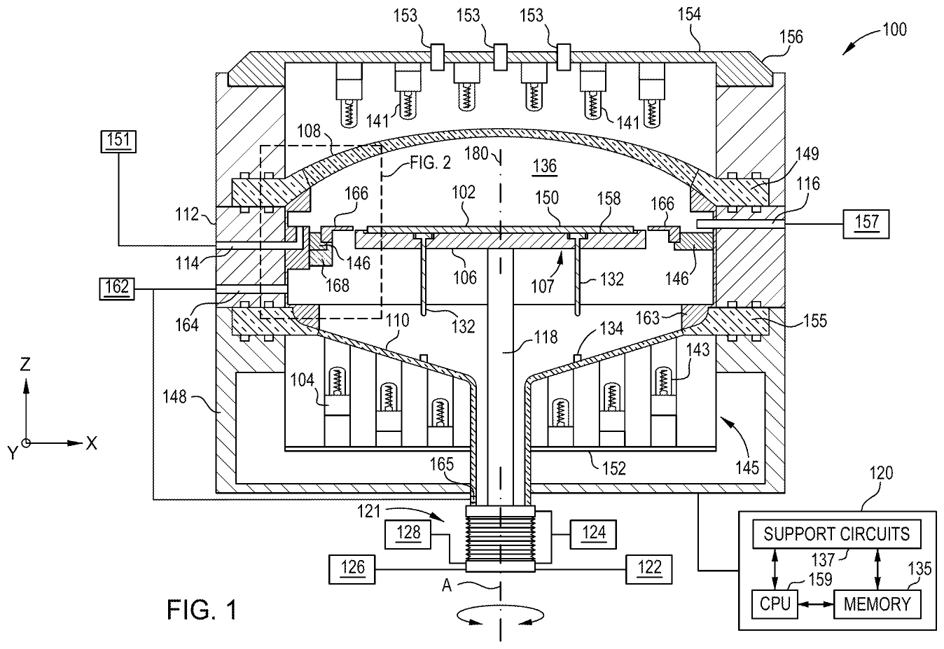

FIG. 1 is a schematic cross-sectional side view of a process chamber 100, such as a deposition chamber. In one example, the process chamber 100 is an epitaxial deposition chamber. The process chamber 100 is utilized to grow an epitaxial film on a substrate, such as the substrate 102. The process chamber 100 creates a cross-flow of precursors across a top surface 150 of the substrate 102.

The process chamber 100 includes an upper body 156, a lower body 148 disposed below the upper body 156, a flow module 112 disposed between the upper body 156 and the lower body 148. The upper body 156, the flow module 112, and the lower body 148 form a chamber body. The process chamber 100 also includes a substrate support 106, an upper transmissive window 108, a lower transmissive window 110, a plurality of upper lamps 141, and a plurality of lower lamps 143. As shown, the controller 120 is in communication with the process chamber 100 and is used to control processes, such as those described herein. The substrate support 106 is disposed between the upper transmissive window 108 and the lower transmissive window 110. The plurality of upper lamps 141 are disposed between the upper transmissive window 108 and a lid 154. The lid 154 includes a plurality of sensors 153 disposed therein for measuring the temperature within the process chamber 100. The plurality of lower lamps 143 are disposed between the lower transmissive window 110 and a floor 152. The plurality of lower lamps 143 form a lower lamp assembly 145.

A process volume 136 is formed between the upper transmissive window 108 and the lower transmissive window 110. The upper transmissive window 108 may have a dome shape or be substantially flat. The upper transmissive window 108 is supported by an upper support ring 149. The upper support ring 149 is coupled to an outer edge of the upper transmissive window 108 and is disposed between the upper body 156 and the flow module 112. The upper transmissive window 108 is light transmissive and may comprise a quartz material. The lower transmissive window 110 may also be a dome shape or be substantially flat. The lower transmissive window 110 has an opening in the center for a shaft 118 of the substrate support 106 to be disposed therethrough. The lower transmissive window 110 is supported at an outer edge by a lower support ring 155. The lower support ring 155 is disposed between the lower body 148 and the flow module 112. The lower transmissive window 110 is light transmissive and may comprise a quartz material.

The substrate support 106 is disposed in the process volume 136. The substrate support 106 includes a top surface 158 on which the substrate 102 is disposed. The substrate support 106 is attached to the shaft 118. The shaft is connected to a motion assembly 121. The motion assembly 121 includes one or more actuators and/or adjustment devices that provide movement and/or adjustment of the shaft 118 and/or the substrate support 106 within the process volume 136. In one example, the motion assembly 121 includes a rotary actuator 122 that rotates the shaft 118 and/or the substrate support 106 about a longitudinal axis A of the process chamber 100. The motion assembly 121 further includes a vertical actuator 124 to lift and lower the substrate support 106 in the z-direction (e.g., vertical axis). The motion assembly includes a tilt adjustment device 126 that is used to adjust the planar orientation of the substrate support 106 relative to the axis A and a lateral adjustment device 128 that is used to adjust the position of the shaft 118 and the substrate support 106 side to side (i.e., in the x/y plane) within the process volume 136.

The substrate support 106 includes lift pin holes 107. Each of the lift pin holes 107 is sized to accommodate a respective lift pin 132. The lift pins 132 are used to lift the substrate 102 from the substrate support 106. The lift pins 132 may rest on lift pin stops 134 when the substrate support 106 is lowered from a processing position to a transfer position. The lift pin stops 134 cause the lift pins 132 to extend through the substrate support 106 as the substrate support 106 is lowered, thus lifting the substrate 102 from the substrate support 106 to facilitate access to the underside of the substrate 102 for robotic transfer.

In one or more embodiments, the flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. In one or more embodiments, a shield 146 is disposed below the plurality of process gas inlets 114 and the one or more exhaust gas outlets 116. The shield 146 is coupled to the flow module 112. The shield 146 is disposed above the purge gas inlets 164. The shield 146 is configured to support a pre-heat ring 166 and guide gas flow. In some embodiments, the shield 146 extends vertically above the pre-heat ring to guide a process gas flow path. A liner 163 is disposed on the inner surface of the flow module 112 to protect the flow module 112 from reactive gases used during deposition processes. The process gas inlets 114 and the purge gas inlets 164 are positioned to maintain a flow of a process gas substantially parallel to the top surface 150 of a substrate 102 disposed within the process volume 136. The process gas inlets 114 are fluidly connected to a process gas source 151. The purge gas inlets 164, 165 are fluidly connected to a purge gas source 162. In some embodiments, a second plurality of purge gas inlets 165 may be disposed within the lower transmissive window 110 near the motion assembly 121 so as to create an upward flow path circumferentially around the shaft 118 allowing the purge gas to enter the process volume 136. The one or more exhaust gas outlets 116 are fluidly connected to an exhaust pump 157. Each of the process gas source 151 and the purge gas source 162 may be configured to supply one or more precursors or process gases into the process volume 136.

In some embodiments, at least one heater 168 is disposed adjacent to the pre-heat ring 166 within the process chamber 100. The heater 168 is used to heat the pre-heat ring 166. Heat radiating from the pre-heat ring 166 increases the activation energy of the process gasses flowing over the pre-heat ring 166 towards the top surface 150 of the substrate 102. The pre-heat ring 166 is disposed over and around an outer edge of the substrate support 106, such that there is an overlaps and a gap defined between the innermost vertical surface of the pre-heat ring 166 and the outermost horizontal surface of the substrate support 106. The pre-heat ring 166 may be formed of one or more parts. The pre-heat ring 166 has a top surface which is parallel to the direction of gas flow across the top surface 150 of the substrate 102 and the substrate support 106. In some embodiments, the top surface of the pre-heat ring 166 is substantially flat allowing for the process gas to flow at, or substantially near, a 90 degree angle relative to a centerline 180 of the processing chamber.

In some embodiments, the heater 168 is disposed beneath the pre-heat ring 166, such that the heater 168 contacts the pre-heat ring 166 and formed through a wall of the flow module 112 and the liner 163. In some embodiments, the pre-heat ring is directly coupled to a power source to heat the pre-heat ring by conduction. The power source is coupled to a controller 120 that controls the operation of the heater 168, among other processing system components.

The controller 120 includes a central processing unit (CPU) 159 (e.g., a processor), a memory 135 containing instructions, and support circuits 137 for the CPU 159. The controller 120 controls various items directly, or via other computers and/or controllers. In one or more embodiments, the controller 120 is communicatively coupled to dedicated controllers, and the controller 120 functions as a central controller.

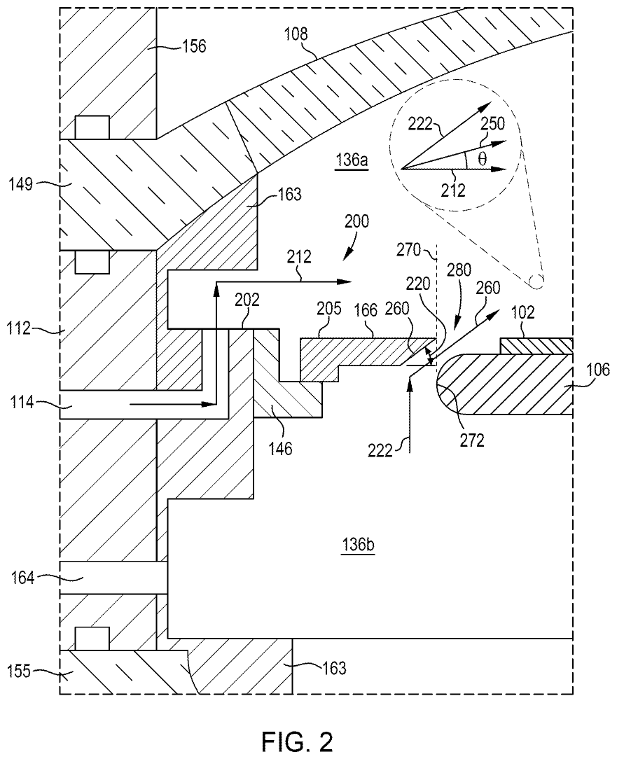

FIG. 2 is a partial schematic partial cross-sectional view of a pre-heat ring assembly 200 of the process chamber 100 of FIG. 1. The process volume 136 comprises an upper process volume 136a and a lower process volume 136b divided by the pre-heat ring assembly 200 and the substrate support 106. The pre-heat ring assembly 200 includes the pre-heat ring 166 and the shield 146. In some embodiments, the liner 163 is disposed on the innermost surfaces of the flow module 112 and the upper and lower support rings 149, 155. The liner 163 protects the flow module 112 and the upper and lower support rings 149, 155 from undesired deposition. The flow module 112 includes the plurality of process gas inlets 114 coupled to a gas inlet surface 202 disposed adjacent to the pre-heat ring 166. The pre-heat ring 166 has an annular shape and is depicted with a tapered wall 260. While the taper wall 260 is illustrated as coming to an end point 210 near the innermost surface of the pre-heat ring 166 as a sharp point, it is contemplated that the end point 210 may be a rounded, curved, concave or convex, shaped as a gear (e.g., a toothed wheel), substantially flat, chamfered, the like, or some combination thereof. In some embodiments, the end point 210 overlaps the outermost edge of the substrate support 106. The overlap 270 encourages the purge gas flow path 222 to maintain an angled trajectory while enabling the substrate support to move up towards the pre-heat ring 166 for processing. In some embodiments, the outermost edge 272 of the substrate support 106 has a tapered body, parallel to the taper wall 260, to further encourage the purge flow path 222 trajectory. In some embodiments, a gap 280 is defined between the overlapped pre-heat ring 166 and the substrate support 106. The gap 280 may be narrowed by a movement of the substrate support in the upward direction such that the purge flow through the gap 280 is choked. The choked purge gas flow reduces the amount of purge gas flow into the upper processing volume 136a.

During a deposition operation, the process gas inlets 114 direct the process gas inward toward the upper process volume 136a. The flow of the process gas traverses the process gas inlet 114 to flow upwards and then laterally towards the exhaust gas outlets 116 (shown in FIG. 1), while flowing over the substrate 102 to deposit a film. The purge gas inlets 164, 165 direct a flow of purge gas into the lower processing volume 136b. The purge gas flows out of the purge gas inlets 164 (and 165 of FIG. 1) and into the lower processing volume 136b. The purge gas reduces the amount of processing gas from the upper processing volume 136a from entering the lower processing volume 136b. Reduction in the amount of the process gas (i.e., reactive gases) into the lower processing volume 136b beneficially reduces the amount of material deposited on the substrate because the process gas is maintained within the upper processing volume 136a. As process gas migration into the lower processing volume 136b is discouraged by the purge gas flow, undesired deposition in the lower processing volume 136b is effectively reduced, thus leading to a decrease in cleaning frequency. In some embodiments, the purge gas is a non-reactive gas (i.e., inert gas), such as Helium (He), Neon (Ne), Argon (Ar), Krypton (Kr), Xenon (Xe) or Radon (Rn). In some embodiments, the purge gas is injected into the lower processing volume 136b at a higher pressure than the process gas so that the purge gas flows into the upper processing volume 136a. In some embodiments, combinable with other embodiments, the process gas is injected into the upper processing volume 136a at a higher flow rate (or velocity) causing suction of the purge gas at the gap 280 so that the purge gas flows into the upper processing volume 136a.

In some embodiments, the process parameters that maintain a continuous flow of purge gas into the upper processing volume 136a are programmed into the controller 120 to initiate process controls to adjust flowrates (e.g., volume or mass flowrate) of the processing gas, purge gas, temperature, or pressure of the chamber.

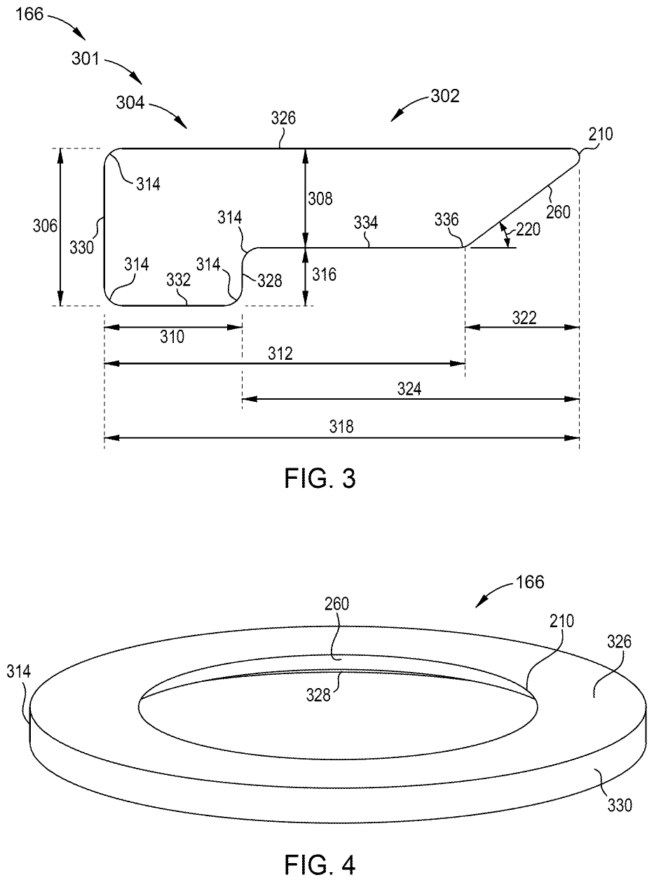

The flow path 212 of the processing gas within the upper processing volume 136a mixes with the purge gas traveling along flow path 222 into the upper processing volume 136a from the gap 280 disposed between the substrate support 106 and the pre-heat ring 166. The purge gas flow path 222 into the upper processing volume 136a is guided by the angle 220 of the taper wall 260 of the pre-heat ring 166. For example, the taper wall 260 of the pre-heat ring 166 guides the purge gas at an angle less than 90 degrees but greater than 0 degrees into the upper processing volume 136a. Details of the taper wall 260 are discussed in FIG. 3, below. The purge gas of flow path 222 interrupts the lateral process gas of flow path 212, mixing the gases and resulting in a gas flow resultant 250 of less than 45 degrees relative to the substrate 102. The gas flow resultant 250 advantageously reduces the angle of flow towards chamber components, such as the upper transmissive window 108, and therefore reduces the amount of undesirable deposition on those chamber components. Additionally, a reduction of undesired deposition increases cleaning efficiency as chamber cleaning cycles are reduced due to reduced unintended depositions. Furthermore, the gas flow resultant 250 concentrates the process gas toward a center of the substrate 102 to improve uniform film depositions across the substrate 102.

Similar to a deposition process, a first cleaning cycle utilizes the advantageous configuration of the pre-heat ring 166 with a taper wall 260, as described above. Due to the cleaning gas being directed in an upward direction (e.g., the gas flow resultant 250 path), the cleaning gas has improved cleaning of chamber components, such as the upper transmissive window 108. In a cleaning cycle, a purge gas is flowed into the lower processing volume 136b. The purge gas flows into the upper processing volume 136a and pushes the cleaning gas towards chamber components exposed to the upper processing volume 136a that may have undesired material deposited thereon. As the purge gas directs greater amounts of cleaning gas into contact with chamber components exposed in the upper processing volume 136a, deposit removal and cleaning efficiency are substantially improved resulting in desirably longer intervals between cleaning cycles.

In some embodiments, a second cleaning cycle is performed to clean the lower transmissive window 110 of FIG. 1. The substrate support 106 is actuated away from the pre-heat ring 166 (i.e., in a downward direction) to increase the distance in gap 280. An increased gap 280 is advantageous for cleaning the lower transmissive window 110 as cleaning gas enters the lower processing volume 136b from the upper processing volume 136a. In some embodiments, the pressure of the purge gases within the lower processing volume 136b is decreased by controller 120 instructions to reduce the flow resistance of the cleaning gases flowing into the lower processing volume 136b. Alternatively, the pressure and/or flowrate of the cleaning gases in the upper processing volume 136a are increased to encourage flow into the lower processing volume 136b. In some embodiments, a combination of increased pressure and/or flowrate of the cleaning gas, and a reduction of pressure of the purge gas are used to enable cleaning of the lower transmissive window 110. Furthermore, it is contemplated that the first cleaning cycle and the second cleaning cycles are stages of a single cleaning cycle. For example, at stage 1, the upper transmissive window 108 may be cleaned for a predetermined amount of time and then at stage 2, the lower transmissive window 110 is cleaned for a predetermined amount of time. In some embodiments, the second cleaning cycle is performed less frequent than the first cleaning cycle.

FIG. 3 is a schematic cross-sectional view of the pre-heat ring 166 of FIG. 1, according to one embodiment. The pre-heat ring 166 has a tapered body 301 comprising an inner portion 302 and an outer portion 304 that share a top surface 326. The terms “inner” and “outer” are to be understood as referencing the respective term from a center of the ring 166, thereby the term “inner” is an area closest to the center of the 166 ring and the term “outer” is an area farther from the center of the ring 166. The body 301 has a height 306 of about 2 mm to about 8 mm, such as about 3 mm to about 7 mm, such about 4 mm to about 6 mm, such as about 5 mm. The body 301 has a length 318 of about 30 mm to about 70 mm, such as about 40 mm to about 60, such about 50 mm. The outer portion 304 comprises a portion of the top surface 326, an inner surface 328, a bottom surface 332, and an outer surface 330. The outer portion 304 has a height 306 (same as height 306 of body 301) and a length 310 of about 2 mm to about 25 mm, such as about 3 mm to about 15 mm, such as about 4 mm to about 10 mm, such as about 5 mm to about 7 mm, such as about 5 mm. The inner portion 302 comprises a portion of the top surface 326, a bottom surface 334, and the taper wall 260. The taper wall 260 extends from a starting point 336 to the end point 210. The taper wall 260 length is about 1 mm to about 30 mm, such as about 1 mm to about 25 mm, such as about 1 mm to about 20, such as about 1 mm to about 16 mm, such as about 1 mm to about 10 mm, such as about 1 mm to about 5 mm, such about 1 mm to about 3 mm, such as about 2 mm to about 30 mm, such as about 3 mm to about 30 mm, such as about 5 mm to about 30 mm, such about 10 mm to about 30 mm, such as about 16 mm to about 30 mm, such as about 20 mm to about 30 mm, such as about 25 mm to about 30 mm, such as about greater than about 1 mm, greater than about 2 mm, greater than about 3 mm, greater than about 5 mm, greater than about 10 mm, greater than about 16 mm, greater than about 20 mm, greater than about 25 mm, greater than about 29 mm, such as about less than about 30 mm, less than about 25 mm, less than about 20 mm, less than about 16 mm, less than about 10 mm, less than about 5 mm, less than about 3, less than about 2 mm, less than about 1.5 mm, such as about 5 mm to about 20 mm, such as about 7 mm to about 18 mm, such as about 10 mm to about 16 mm, such as about 2 mm to about 10 mm, such as about 2 mm to about 7 mm, such as about 2 mm to about 5 mm, such as about 2 mm to about 3 mm, such as about 20 mm to about 30 mm, to about 23 mm to about 30 mm, such about 26 mm to about 30 mm. Longer lengths of the taper wall 260 enable a blocking effect for reducing the purge gas into the upper processing volume 136a. Shorter lengths of the taper wall 260 enable a flowing effect that increasing the purge gas into the upper processing volume 136a. The inner and outer portions 302, 304 are contiguous between the intersection of the inner surface 328 and the bottom surface 334, extending a vertical length 308 to the top surface 326. The vertical length 316 is about 1 mm to about 21.8 mm, such about 1.4 mm to about 12 mm, such as about 1.6 mm to about 7 mm, such as about 1.6 mm to about 4 mm, such as about 1.6 to about 2 mm, such as about 1.8 mm. The inner portion 302 has a height 308 of about 1 mm to about 23.2 mm, such as about 2.1 mm to about 13.2 mm, such about 2.5 mm to about 10 mm, such as about 2.6 mm to about 7.5 mm, such as about 2.7 mm to about 5 mm, such as about 2.8 mm to about 4 mm, such as about 2.9 mm to about 3.5 mm, such as about 3 mm to about 3.4 mm, such as about 3.2 mm. The inner portion 302 has a length 324 of about 10 mm to about 70 mm, such as about 20 mm to about 60 mm, such about 25 mm to about 55 mm, such as about 30 mm to about 50 mm, such as about 35 mm to about 45 mm, such as about 37 mm to about 43 mm, such as about 40 mm. The start point 336 of the taper wall 260 is on the bottom surface 334 while the end point 210 of the taper wall 260 is on the top surface 326. The horizontal length 322 between the start point 336 and the end point 210 is about 1.5 mm to about 5.5 mm, such about 2 mm to about 5 mm, such as about 2.5 mm to about 4.5 mm, such as about 2.5 mm to about 4 mm, such as about 2.5 mm to about 3.5 mm, such as about 2.8 mm to about 3.2 mm, such as about 3 mm. The horizontal length 322 and the taper wall 260 define an angle 220 of about 1 degree to about 89 degree angle, such as 5 degree to about 85 degree angle, such as about 10 degree to about 80 degree angle, such as about 15 degree to about 75 degree angle, such as about 20 degree to about 70 degree angle, such as about 25 degree to about 65 degree angle, such as about 30 degree to about 60 degree angle, such as about 35 degree to about 55 degree angle, such about 40 degree to about 50 degree angle, such as about 45 degrees, such as greater than about 1 degree angle, greater than about 5 degree angle, greater than about 10 degree angle, greater than about 15 degree angle, greater than about 20 degree angle, greater than about 25 degree angle, greater than about 30 degree angle, greater than about 35 degree angle, greater than about 40 degree angle, greater than about 45 degree angle, greater than about 50 degree angle, greater than about 55 degree angle, greater than about 60 degree angle, greater than about 65 degree angle, greater than about 70 degree angle, greater than about 75 degree angle, greater than about 80 degree angle, greater than about 85 degree angle, such as less than about 80 degree angle, less than about 75 degree angle, less than about 70 degree angle, less than about 65 degree angle, less than about 60 degree angle, less than about 55 degree angle, less than about 50 degree angle, less than about 45 degree angle, less than about 40 degree angle, less than about 35 degree angle, less than about 30 degree angle, less than about 25 degree angle, less than about 20 degree angle, less than about 15 degree angle, less than about 10 degree angle, less than about 5 degree angle. It is to be understood that the angle 220 may geometrically vary the lengths or heights described. The body 301 is illustrated as having edges 314 that are curved. In some embodiments, the rounded edges have a radius of about 0.1 mm to about 5.5 mm, such as about 0.3 mm to about 3 mm, such as about 0.5 to about 1 mm, such as about 0.5 mm to about 0.75 mm, such about 0.5 mm. In other embodiments, the edges 314 are chamfered.

The shape of the pre-heat ring 166 of FIG. 3 is illustrated as having a substantially “L” cross-sectional shape. However, it is contemplated the body 301 may incorporate other geometrical features including, but not limited to, keyed recesses for positioning and longer or short taper features. In some embodiments, the thermal mass of the inner portion 302 of the body 301 exceeds the thermal mass of the outer portion 304 of the pre-heat ring 166. Similarly, the thermal mass of the pre-heat ring 166 disposed above a plane extending along the bottom surface 334 is larger than the thermal mass of the pre-heat ring 166 disposed below the bottom surface 334.

FIG. 4 is a perspective view of the pre-heat ring 166, according to one embodiment. The pre-heat ring 166 is a ring shape comprising features discussed above such as the top surface 326, the end point 210 of the taper wall 260, the inner surface 328, and the outer surface 330. The pre-heat ring 166 may be constructed from graphite, (e.g., such as carbon graphite). In some embodiments, the pre-heat ring 166 is coated with silicon carbide (SiC). The pre-heat ring 166 is capable of processing conditions upwards of about 1300 degrees Celsius, such as about 900 degrees Celsius to about 1300 degrees Celsius, such as about 1000 degrees Celsius to about 1295 degrees Celsius, such as about 1200 degrees Celsius to about 1290 degrees Celsius, such as about 1250 degrees Celsius to about 1285 degrees Celsius, such as about 1270 degrees Celsius to about 1280 degrees Celsius, without warpage. The pre-heat ring 166 has an inner diameter of 90 millimeters (mm) to about 400 mm and an outer diameter of about 200 mm to about 500 mm.

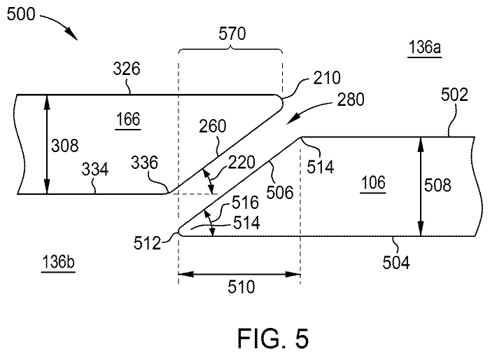

FIG. 5 is an expanded schematic cross sectional view of a pre-heat assembly 500. The pre-heat assembly 500 includes the pre-heat ring 166 and the substrate support 106. In the example depicted in FIG. 5, each of the pre-heat ring 166 and the substrate support 106 have a tapered edge. In some embodiments, the substrate support 106 may have an upper surface 502, a lower surface 504, and a radially outward surface 506. The outward surface 506 connects the upper and lower surfaces 502, 504 to define a disk shape. The upper surface 502 may be substantially flat or may include a recess to position a substrate 102 thereon and/or therein. In some embodiments, the upper surface 502 is parallel to the lower surface 504 and separated by a length 508 of about 2 mm to about 25 mm, such as about 3 mm to about 15 mm, such as about 4 mm to about 10 mm, such as about 5 mm to about 7 mm, such as about 5 mm. In some embodiments, the radially outward surface 506 may have a taper that is substantially parallel to the taper wall 260 of pre-heat ring 166. In some embodiments, the radially outward surface 506 may have an angle 516 that is greater than the angle 220 such that the gap 280 narrows towards the direction of the upper surface 502 causing a pinch (i.e., restriction) of the gap 280. The pinch in the gap 280 advantageously chokes the flow of purge gas passing through gap 280, thereby controlling the amount of purge gas flowing into the upper processing volume 136a. In some examples, the angle 516 may be about 1 degree to about 89 degrees, such as 5 degree to about 85 degree angle, such as about 10 degree to about 80 degree angle, such as about 15 degree to about 75 degree angle, such as about 20 degree to about 70 degree angle, such as about 25 degree to about 65 degree angle, such as about 30 degree to about 60 degree angle, such as about 35 degree to about 55 degree angle, such about 40 degree to about 50 degree angle, such as about 45 degrees, such as greater than about 1 degree angle, greater than about 5 degree angle, greater than about 10 degree angle, greater than about 15 degree angle, greater than about 20 degree angle, greater than about 25 degree angle, greater than about 30 degree angle, greater than about 35 degree angle, greater than about 40 degree angle, greater than about 45 degree angle, greater than about 50 degree angle, greater than about 55 degree angle, greater than about 60 degree angle, greater than about 65 degree angle, greater than about 70 degree angle, greater than about 75 degree angle, greater than about 80 degree angle, greater than about 85 degree angle, such as less than about 80 degree angle, less than about 75 degree angle, less than about 70 degree angle, less than about 65 degree angle, less than about 60 degree angle, less than about 55 degree angle, less than about 50 degree angle, less than about 45 degree angle, less than about 40 degree angle, less than about 35 degree angle, less than about 30 degree angle, less than about 25 degree angle, less than about 20 degree angle, less than about 15 degree angle, less than about 10 degree angle, less than about 5 degree angle. The radially outward surface 506 may have a length of about 1 mm to about 30 mm, such as about 1 mm to about 25 mm, such as about 1 mm to about 20, such as about 1 mm to about 16 mm, such as about 1 mm to about 10 mm, such as about 1 mm to about 5 mm, such about 1 mm to about 3 mm, such as about 2 mm to about 30 mm, such as about 3 mm to about 30 mm, such as about 5 mm to about 30 mm, such about 10 mm to about 30 mm, such as about 16 mm to about 30 mm, such as about 20 mm to about 30 mm, such as about 25 mm to about 30 mm, such as about greater than about 1 mm, greater than about 2 mm, greater than about 3 mm, greater than about 5 mm, greater than about 10 mm, greater than about 16 mm, greater than about 20 mm, greater than about 25 mm, greater than about 29 mm, such as about less than about 30 mm, less than about 25 mm, less than about 20 mm, less than about 16 mm, less than about 10 mm, less than about 5 mm, less than about 3, less than about 2 mm, less than about 1.5 mm, such as about 5 mm to about 20 mm, such as about 7 mm to about 18 mm, such as about 10 mm to about 16 mm, such as about 2 mm to about 10 mm, such as about 2 mm to about 7 mm, such as about 2 mm to about 5 mm, such as about 2 mm to about 3 mm, such as about 20 mm to about 30 mm, to about 23 mm to about 30 mm, such about 26 mm to about 30 mm. The radially outward surface 506 may have horizontal length 510 of about 1.5 mm to about 5.5 mm, such about 2 mm to about 5 mm, such as about 2.5 mm to about 4.5 mm, such as about 2.5 mm to about 4 mm, such as about 2.5 mm to about 3.5 mm, such as about 2.8 mm to about 3.2 mm, such as about 3 mm.

While the radially outward surface 506 is illustrated as extending to a curved end point 512 near the outmost surface of the substrate support 106, it is contemplated that the end point 512 may be a rounded, curved, concave or convex, shaped as a gear (e.g., a toothed wheel), substantially flat, chamfered, the like, or some combination thereof. In one or more embodiments, the end point 512 is disposed below the pre-heat ring 166. An overlap 570, defined horizontally between end point 512 of the substrate support 106 and the end point 210 of the pre-heat ring 166, encourages gas traveling along the purge gas flow path 222 (of FIG. 2) to maintain an angled trajectory while enabling the substrate support to move up towards the pre-heat ring 166 for processing. In some embodiments, the gap 280 between the overlapped pre-heat ring 166 and the substrate support 106 is narrowed by a movement of the substrate support in the upward direction such that the purge flow through the gap 280 is choked. Choking the purge gas flow controls (for example, reduces) the amount of purge gas flow into the upper processing volume 136a.

The edges 514 of the substrate support 106 are rounded having a radius of about 0.1 mm to about 5.5 mm, such as about 0.3 mm to about 3 mm, such as about 0.5 to about 1 mm, such as about 0.5 mm to about 0.75 mm, such about 0.5 mm. In some embodiments, the edges 514 are chamfered.

All numerical values are “about” or “approximately” the indicated value, and take into account experimental error and variations that would be expected by a person having ordinary skill in the art. For example, + or −10% of the value indicated may be used to describe the term “about” or “approximately”. In another example, + or −10% degrees is used to describe the experimental error and variations of an angle, such as the term “substantially flat” or “substantially parallel.”

While the foregoing is directed to embodiments of the present disclosure, other and further embodiments of the disclosure may be devised without departing from the basic scope thereof, and the scope thereof is determined by the claims that follow.

What is claimed is:

1. A process chamber for film deposition comprising:
a process chamber having a chamber volume;
a substrate support disposed in the chamber volume, the substrate support having a radially outward surface; and
a pre-heat ring surrounding the substrate support, the pre-heat ring comprising:
a tapered wall facing the radially outward surface, the tapered wall narrows towards a top surface of the pre-heat ring and towards the substrate support.

2. The process chamber of claim 1, wherein the radially outward surface of the substrate support is substantially flat.

3. The process chamber of claim 1, wherein the tapered wall is substantially flat.

4. The process chamber of claim 1, wherein the tapered wall is substantially parallel to the radially outward surface.

5. The process chamber of claim 4, wherein the top surface is substantially flat.

6. The process chamber of claim 1, wherein the pre-heat ring further comprises:
a top surface;
an outer bottom surface disposed parallel to the top surface;
an outer wall extending between the top surface and the outer bottom surface;
an inner wall, the inner wall disposed substantially parallel to the outer wall and extending from the outer bottom surface toward the top surface, at least a portion of the top surface extending radially inward of the inner wall; and
an inner bottom surface, the inner bottom surface disposed substantially parallel to the outer bottom surface and extending radially inward from the inner wall.

7. The process chamber of claim 6, wherein the tapered wall extends between the top surface and the inner bottom surface of the pre-heat ring.

8. The process chamber of claim 7, wherein the tapered wall extends at an angle greater than 0 degrees and less than 90 degrees relative to plane of the inner bottom surface, the tapered wall having a length of about 1 millimeter (mm) to about 30 mm.

9. A pre-heat ring for a substrate processing chamber, the pre-heat ring comprising:
an annular body of the pre-heat ring, the annular body comprising:
a top surface;
an outer bottom surface disposed parallel to the top surface;
an outer wall extending between the top surface and the outer bottom surface;
an inner wall, the inner wall disposed substantially parallel to the outer wall and extending from the outer bottom surface toward the top surface, at least a portion of the top surface extends radially inward of the inner wall;
an inner bottom surface, the inner bottom surface disposed substantially parallel to the outer bottom surface and extending radially inward from the inner wall; and
a tapered wall, the tapered wall extending between to the top surface and the inner bottom surface, the tapered wall at an angle greater than 0 degrees and less than 90 degrees relative to inner bottom surface, the tapered wall having a length of about 1 millimeter (mm) to about 30 mm.

10. The pre-heat ring of claim 9, wherein the tapered wall is about 1 mm to about 16 mm.

11. The pre-heat ring of claim 9, wherein the top surface is substantially flat.

12. The pre-heat ring of claim 9, wherein the top surface has a length of about 30 mm to about 70 mm.

13. The pre-heat ring of claim 9, wherein the tapered wall is angled at about 20 degrees to about 70 degrees.

14. The pre-heat ring of claim 9, wherein the annular body is constructed from graphite.

15. The pre-heat ring of claim 14, wherein the annular body is constructed from silicon carbide coated carbon graphite.

16. The pre-heat ring of claim 9, wherein a thermal mass between a plane aligned with the inner bottom surface and the top surface is greater than a thermal mass between the plane aligned with the an inner bottom surface and the outer bottom surface.

17. The pre-heat ring of claim 9, wherein a thermal mass between a plane aligned with the inner wall and the outer wall is less than a thermal mass between the plane aligned with the inner wall and an intersection of the top surface and the tapered wall.

18. The pre-heat ring of claim 9, wherein the annular body has an outer diameter of about 200 mm to about 500 mm.

19. The pre-heat ring of claim 9, wherein the annular body has an inner diameter of about 90 mm to about 400 mm.

20. The pre-heat ring of claim 9, wherein a length of the top surface is longer than a combined length of the inner bottom surface and the outer bottom surface.
